(19) United States
(12) Patent Application Publication
(10) Pub. No.: US 2009/0130827 A1
(43) Pub. Date: May 21, 2009

(54) INTRINSIC AMORPHOUS SILICON LAYER

(76) Inventors: Soo Young Choi, Fremont, CA (US); Yong-Kee Chae, Pleasanton, CA (US); Shuran Sheng, Santa Clara, CA (US); Liwei Li, Sunnyvale, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 12/263,032

(22) Filed: Oct. 31, 2008

Related U.S. Application Data
(60) Provisional application No. 60/985,195, filed on Nov. 2, 2007.

(51) Int. Cl. H01L 21/20

(52) U.S. Cl. 438/486; 257/E21.133

(57) ABSTRACT

Embodiments of the present invention may include an improved thin film solar cell device that is formed by sequentially depositing an intrinsic amorphous silicon layer and an intrinsic microcrystalline silicon layer during the p-i-n or n-i-p junction formation process. Embodiments of the invention also generally provide a method and apparatus for forming the same. The present invention may be used to advantage to form other single junction, tandem junction, or multi-junction thin film solar cell devices.

### CROSS-REFERENCE TO RELATED APPLICATIONS

This application claims benefit of U.S. Provisional Patent Application Ser. No. 60/985,195, filed Nov. 2, 2007, and entitled “Intrinsic Amorphous Silicon Layer,” which is herein incorporated by reference.

### BACKGROUND OF THE INVENTION

1. Field of the Invention

Embodiments of the present invention generally relate to solar cells and methods and apparatuses for forming the same. More particularly, embodiments of the present invention relate to thin film solar cells and methods and apparatuses for forming the same.

2. Description of the Related Art

Crystalline silicon solar cells and thin film solar cells are two types of solar cells. Crystalline silicon solar cells typically use either mono-crystalline substrates (i.e., single-crystal substrates of pure silicon) or a multi-crystalline silicon substrates (i.e., poly-crystalline or polysilicon). Additional film layers are deposited onto the silicon substrates to improve light capture, form the electrical circuits, and protect the devices. Thin-film solar cells use thin layers of materials deposited on suitable substrates to form one or more p-i-n junctions.

Problems with current thin film solar cells include low efficiency and high cost. Therefore, there is a need for improved thin film solar cells and methods and apparatuses for forming the same in a factory environment.

### SUMMARY OF THE INVENTION

Embodiments of the present invention generally provide a method of forming a p-i-n junction over a substrate, comprising depositing a p-doped silicon layer over a surface of a substrate, depositing an n-doped silicon layer over the surface of the substrate, depositing an intrinsic amorphous silicon layer between the p-doped silicon layer and the n-doped silicon layer, and depositing an intrinsic microcrystalline silicon layer on the intrinsic amorphous silicon layer.

Embodiments of the present invention may further provide a method of forming a p-i-n junction over a substrate, comprising depositing a p-doped silicon layer over a surface of a substrate, depositing an n-doped silicon layer over the surface of the substrate, depositing an intrinsic amorphous silicon layer between the p-doped silicon layer and the n-doped silicon layer, depositing a first intrinsic microcrystalline silicon layer on the intrinsic amorphous silicon layer by providing hydrogen gas and silane gas at a ratio of greater than about 200:1, and depositing a second intrinsic microcrystalline silicon layer on the first intrinsic microcrystalline silicon layer by providing hydrogen gas and silane gas at a ratio of less than about 200:1.

Embodiments of the present invention may further provide a method of forming a p-i-n junction over a substrate, comprising depositing a p-doped silicon layer over a surface of the substrate in a first process chamber disposed within a first processing system, transferring the substrate from the first process chamber to a second process chamber which is disposed within the first processing system, wherein transferring the substrate is performed in a vacuum environment, and depositing two or more layers over the surface of the p-doped silicon layer while the substrate is positioned in the second process chamber, comprising depositing an intrinsic amorphous silicon layer on the p-doped silicon layer, depositing an intrinsic microcrystalline silicon layer on the intrinsic amorphous silicon layer, and depositing an n-doped silicon layer on the intrinsic microcrystalline silicon layer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic diagram of a multi-junction solar cell oriented toward the light or solar radiation according to one embodiment of the invention.

FIG. 2 is a schematic cross-section view of one embodiment of a plasma enhanced chemical vapor deposition (PECVD) chamber.

FIG. 3A is a plan schematic view of a processing system according to one embodiment of the invention.

FIG. 3B is a plan schematic view of a processing system according to one embodiment of the invention.

FIG. 4 is a flow chart of one embodiment of forming a p-i-n junction according to one embodiment of the invention.

FIG. 5 is a schematic diagram of a multi-junction solar cell oriented toward the light or solar radiation according to one embodiment of the invention.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

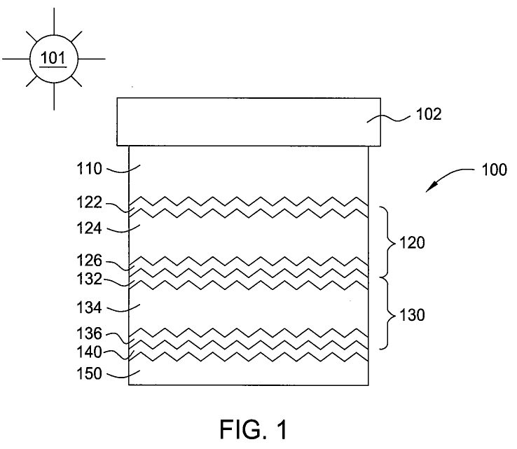

Embodiments of the present invention include improved thin film solar cells and methods and apparatus for forming the same. For ease and clarity of description, the present invention will be described in reference to the tandem junction solar cell of FIG. 1, although, the present invention may be used to advantage to form other single junction, tandem junction, or multi-junction solar cells.

FIG. 1 is a schematic diagram of a multi-junction solar cell 100 oriented toward the light or solar radiation 101. Solar cell 100 comprises a substrate 102, such as a glass substrate, polymer substrate, or other suitable transparent substrate, with thin films formed thereover. The solar cell 100 further comprises a first transparent conducting oxide (TCO) layer 110 formed over the substrate 102, a first p-i-n junction 120 formed over the first TCO layer 110, a second p-i-n junction 130 formed over the first p-i-n junction 120, a second TCO layer 140 formed over the second p-i-n junction 130, and a metal back layer 150 formed over the second TCO layer 140. To improve light absorption by reducing light reflection, the substrate and/or one or more of thin films formed thereover may be optionally textured by wet, plasma, ion, and/or mechanical processes. For example, in the embodiment shown in FIG. 1, the first TCO layer 110 is textured and the subsequent thin films deposited thereover will generally follow the topography of the surface below it.

The first TCO layer 110 and the second TCO layer 140 may each comprise tin oxide, zinc oxide, indium tin oxide, cadmium stannate, doped materials thereof combinations thereof, or other suitable materials. It is understood that the TCO materials may also include additional dopants and components. For example, zinc oxide may further include dopants, such as aluminum, gallium, boron, and other suitable dopants. Zinc oxide preferably comprises 5 atomic % or less of dopants, and more preferably comprises 2.5 atomic % or less aluminum. For example, tin oxide may further include dopants such as fluorine. In certain instances, the substrate 102 may be provided by the glass manufacturers with the first TCO layer 110 already provided.

The first p-i-n junction 120 comprises a p-doped silicon layer 122, an intrinsic silicon layer 124, and an n-doped silicon layer 126. The second p-i-n junction 130 comprises a p-doped silicon layer 132, an intrinsic silicon layer 134, and an n-doped silicon layer 136. In certain embodiments, the intrinsic silicon layer 124 of the first p-i-n junction 120 comprises an amorphous silicon layer whereas the intrinsic silicon layer 134 of the second p-i-n junction 130 comprises a microcrystalline silicon layer, since the amorphous silicon intrinsic layer and the microcrystalline silicon intrinsic layer absorb different regions of the solar spectrum. In one embodiment, the p-doped silicon layer 122, the intrinsic silicon layer 124, and the n-doped silicon layer 126 are each formed from an amorphous silicon containing layer. In one embodiment, the p-doped silicon layer 132 and the intrinsic silicon layer 134 are each formed from a microcrystalline silicon containing layer, and the n-doped silicon layer 136 is formed from an amorphous silicon containing layer. It is believed that using an n-type amorphous silicon layer 136 over a p-doped microcrystalline silicon layer 132 and the intrinsic microcrystalline silicon layer 134 in the second p-i-n junction 130 provides increased cell efficiency since the n-type amorphous silicon layer 136 is more resistant to attack from oxygen, such as the oxygen in air. Oxygen may attack the silicon films and thus forming impurities which lower the capability of the films to participate in electron/hole transport therethrough. It is also believed that the lower electrical resistivity of an amorphous silicon layer versus a crystalline silicon layer in the formed solar cell structure/device will have improved electrical properties due to the reduced affect of unwanted shunt paths on the power generation in the formed second p-i-n junction 130. Shunt paths, which generally extend vertically through the formed p-i-n layers, degrade the solar cells performance by shorting out local lateral regions of the formed solar cell device. Therefore, since the lateral resistance of the amorphous n-type layer (i.e., perpendicular to the vertical direction) is much higher than a crystalline layer the lower the affect that a shunt type defect will have on the rest of the formed solar cell. The reduction in the affect of shunt type defects will improve the solar cell's device performance.

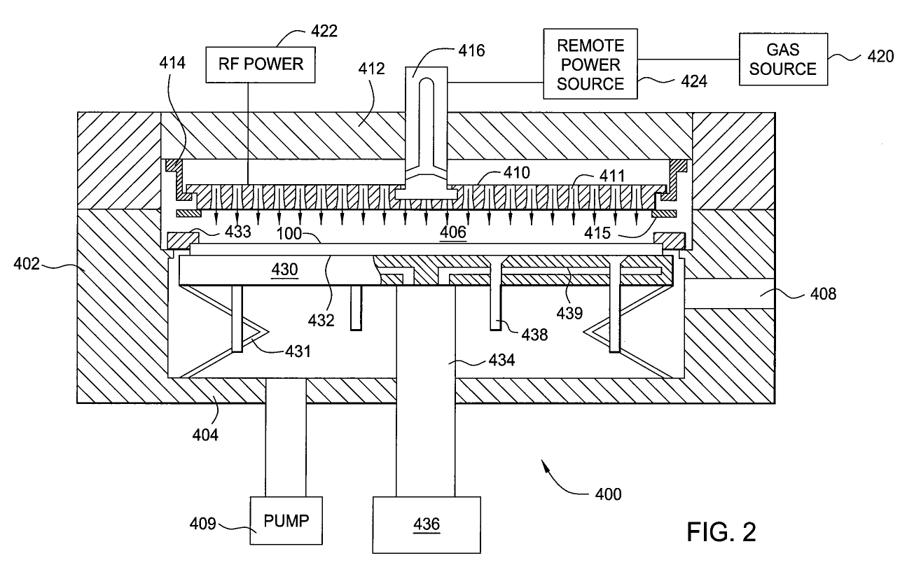

FIG. 2 is a schematic cross-section view of one embodiment of a plasma enhanced chemical vapor deposition (PECVD) chamber 400 in which one or more films of a solar cell, such as one or more silicon layers of the first p-i-n junction 120 and/or the second p-i-n junction 130 of the solar cell 100 of FIG. 1, may be deposited. One suitable plasma enhanced chemical vapor deposition chamber is available from Applied Materials, Inc., located in Santa Clara, Calif. It is contemplated that other deposition chambers, including those from other manufacturers, may be utilized to practice the present invention.

The chamber 400 generally includes walls 402, a bottom 404, and a showerhead 410, and substrate support 430 which define a process volume 406. The process volume is accessed through a valve 408 such that the substrate, such as substrate 102, may be transferred in and out of the chamber 400. The substrate support 430 includes a substrate receiving surface 432 for supporting a substrate and stem 434 coupled to a lift system 436 to raise and lower the substrate support 430. A shadow from 433 may be optionally placed over periphery of the substrate 102. Lift pins 438 are moveably disposed through the substrate support 430 to move a substrate to and from the substrate receiving surface 432. The substrate support 430 may also include heating and/or cooling elements 439 to maintain the substrate support 430 at a desired temperature. The substrate support 430 may also include grounding straps 431 to provide RF grounding at the periphery of the substrate support 430. Examples of grounding straps are disclosed in U.S. Pat. No. 6,024,044 issued on Feb. 15, 2000 to Law et al. and U.S. patent application Ser. No. 11/613,934 filed on Dec. 20, 2006 to Park et al., which are both incorporated by reference in their entirety to the extent not inconsistent with the present disclosure.

The showerhead 410 is coupled to a backing plate 412 at its periphery by a suspension 414. The showerhead 410 may also be coupled to the backing plate by one or more center supports 416 to help prevent sag and/or control the straightness/curvature of the showerhead 410. A gas source 420 is coupled to the backing plate 412 to provide gas through the backing plate 412 and through the holes 411 formed in the showerhead 410 to the substrate receiving surface 432. A vacuum pump 409 is coupled to the chamber 400 to control the process volume 406 at a desired pressure. An RF power source 422 is coupled to the backing plate 412 and/or to the showerhead 410 to provide a RF power to the showerhead 410 so that an electric field is created between the showerhead and the substrate support so that a plasma may be generated from the gases between the showerhead 410 and the substrate support 430. Various RF frequencies may be used, such as a frequency between about 0.3 MHz and about 200 MHz. In one embodiment the RF power source is provided at a frequency of 13.56 MHz. Examples of showerheads are disclosed in U.S. Pat. No. 6,477,980 issued on Nov. 12, 2002 to White et al., U.S. Publication 20050251990 published on Nov. 17, 2006 to Choi et al., and U.S. Publication 2006/0060138 published on Mar. 23, 2006 to Keller et al, which are all incorporated by reference in their entirety to the extent not inconsistent with the present disclosure.

A remote plasma source 424, such as an inductively coupled remote plasma source, may also be coupled between the gas source and the backing plate. Between processing substrates, a cleaning gas may be provided to the remote plasma source 424 so that a remote plasma is generated and provided to clean chamber components. The cleaning gas may be further excited by the RF power source 422 provided to the showerhead. Suitable cleaning gases include but are not limited to NF₃, F₂, and SF₆. Examples of remote plasma sources are disclosed in U.S. Pat. No. 5,788,778 issued Aug. 4, 1998 to Shang et al, which is incorporated by reference to the extent not inconsistent with the present disclosure.

In one embodiment, the heating and/or cooling elements 439 may be set to provide a substrate support temperature during deposition of about 400 degrees Celsius or less, preferably between about 100 degrees Celsius and about 400 degrees Celsius, more preferably between about 150 degrees Celsius and about 300 degrees Celsius, such as about 200 degrees Celsius.

For deposition of silicon films, a silicon-based gas and a hydrogen-based gas are provided. Suitable silicon based gases include, but are not limited to silane (SiH₄), disilane (Si₂H₆), silicon tetrafluoride (SiF₄), silicon tetrachloride (SiCl₄), dichlorosilane (SiH₂Cl₂), and combinations thereof. Suitable hydrogen-based gases include, but are not limited to hydrogen gas (H₂). The p-type dopants of the p-type silicon layers may each comprise a group III element, such as boron or aluminum. Preferably, boron is used as the p-type dopant. Examples of boron-containing sources include trimethylboron (TMB (or B(CH₃)₃)), diborane (B₂H₆), BF₃, B(C₂H₅)₃, and similar compounds. Preferably, TMB is used as the p-type dopant. The n-type dopants of the n-type silicon layer may each comprise a group V element, such as phosphorus, arsenic, or antimony. Preferably, phosphorus is used as the n-type dopant. Examples of phosphorus-containing sources include phosphine and similar compounds. The dopants are typically provided with a carrier gas, such as hydrogen, argon, helium, and other suitable compounds. In the process regimes disclosed herein, a total flow rate of hydrogen gas is provided. Therefore, if a hydrogen gas is provided as the carrier gas, such as for the dopant, the carrier gas flow rate should be subtracted from the total flow rate of hydrogen to determine how much additional hydrogen gas should be provided to the chamber.

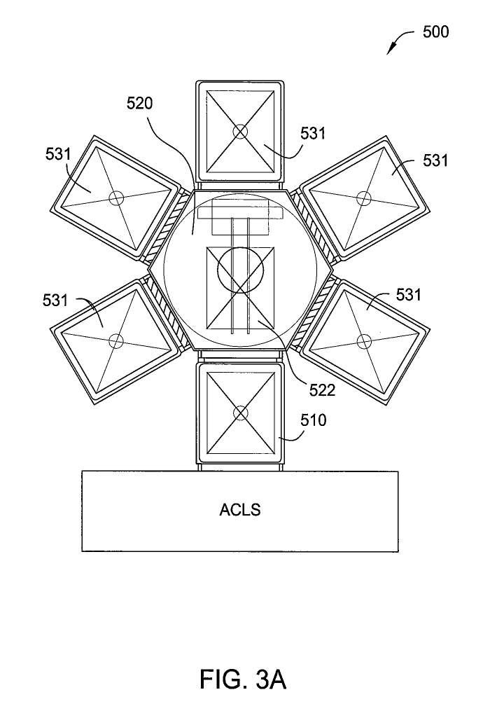

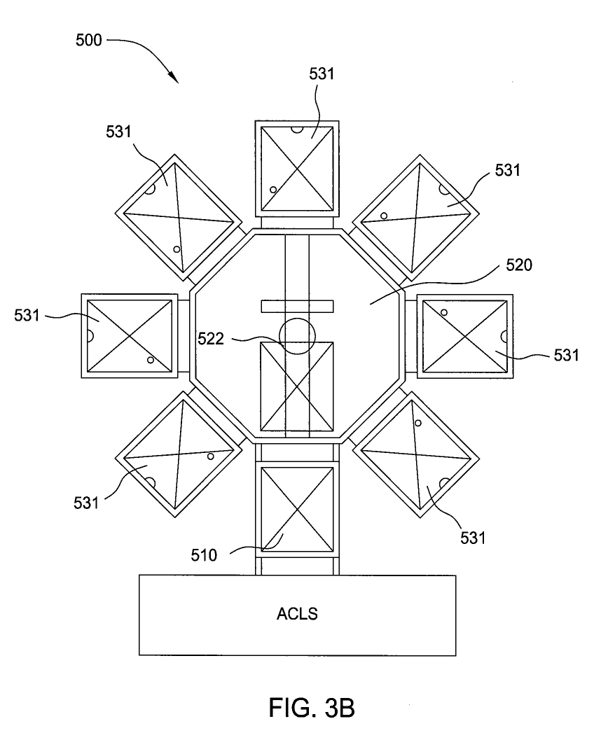

FIG. 3A and FIG. 3B are schematic plan views of embodiments of a process system, or system 500, having a plurality of process chambers 531, such as PECVD chambers chamber 400 of FIG. 2 or other suitable chambers capable of depositing silicon films. The system 500 includes a transfer chamber 520 coupled to a load lock chamber 510 and the process chambers 531. The load lock chamber 510 allows substrates to be transferred between the ambient environment outside the system and vacuum environment within the transfer chamber 520 and process chambers 531. The load lock chamber 510 includes one or more evacuatable regions holding one or more substrate. The evacuatable regions are pumped down during input of substrates into the system 500 and are vented during output of the substrates from the system 500. The transfer chamber 520 has at least one vacuum robot 522 disposed therein that is adapted to transfer substrates between the load lock chamber 510 and the process chambers 531. Five process chambers are shown in FIG. 3A and seven process chambers are shown in FIG. 3B; however, the system may have any suitable number of process chambers.

In certain embodiments of the invention, one system 500 is configured to form at least one p-i-n junction, such as at least one of the p-i-n junctions of FIG. 1. At least one of process chambers 531 is configured to deposit a p-doped silicon layer and at least one of the process chambers 531 is configured to deposit an n-doped silicon layer. In certain aspects it may be advantageous to deposit p-doped silicon layers and n-doped silicon layers in separate process chambers to reduce the chance of contamination from the different dopants. In one embodiment, the intrinsic silicon layer may be deposited in a separate process chamber from the p-doped and n-doped silicon process chambers. However, to increase throughput, the intrinsic silicon layer may be deposited in the same chamber as p-doped silicon deposition or as the same chamber as n-doped silicon deposition.

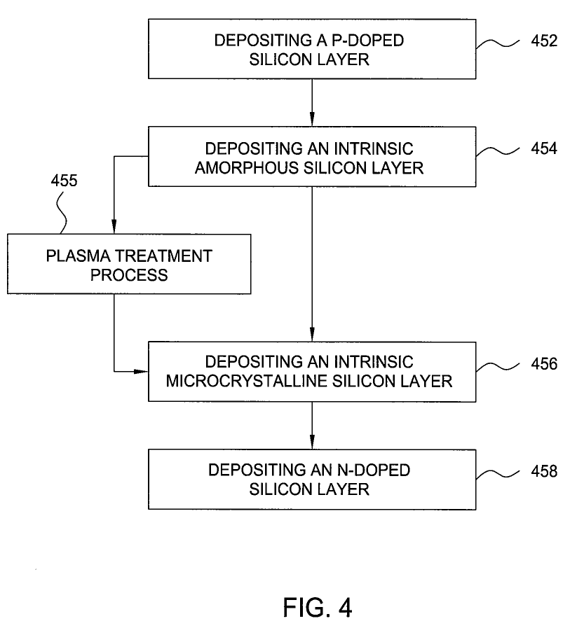

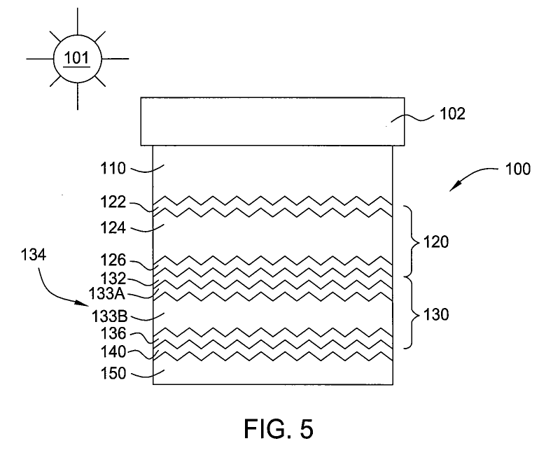

FIG. 4 is a flow chart of one embodiment of forming a second p-i-n junction 130 of FIG. 5. FIG. 5 is a schematic diagram of one embodiment of a multi-junction solar cell 100 oriented toward the light or solar radiation 101 that has an intrinsic silicon layer 134 that is formed from multiple intrinsic type layers, such as an intrinsic amorphous silicon layer 133A and intrinsic microcrystalline silicon layer 133B. FIG. 5 is similar to FIG. 1, which is discussed above, and thus like reference numerals are not re-discussed herein. It should be noted that the order and number of processing steps 452-460 illustrated in FIG. 4 is not intended to be limiting to the scope of the invention described herein, since, for example, a p-i-n junction or an n-i-p junction structure (e.g., switching steps 452 and 458) could be desirably formed without deviating form the basic scope of the invention described herein.

At step 452, a p-doped silicon layer 132 is deposited over a surface of a substrate. In one embodiment, the substrate comprises the substrate 102, the first TCO layer 110 and the first p-i-n junction 120. In one example, a p-doped microcrystalline layer, such as silicon layer 132, comprises providing a gas mixture of hydrogen gas to silane gas in a ratio of about 200:1 or greater. Silane gas may be provided at a flow rate between about 0.1 sccm/L and about 0.8 sccm/L. Hydrogen gas may be provided at a flow rate between about 60 sccm/L and about 500 sccm/L. Trimethylboron may be provided at a flow rate between about 0.0002 sccm/L and about 0.0016 sccm/L. In other words, if trimethylboron is provided in a 0.5% molar or volume concentration in a carrier gas, then the dopant/carrier gas mixture may be provided at a flow rate between about 0.04 sccm/L and about 0.32 sccm/L. An RF power between about 50 milliWatts/cm² and about 700 milliWatts/cm² may be provided to the showerhead. The pressure of the chamber may be maintained between about 1 Torr and about 100 Torr, preferably between about 3 Torr and about 20 Torr, more preferably between 4 Torr and about 12 Torr. The deposition rate of the p-type microcrystalline silicon layer may be about 10 Å/min or more. The p-type microcrystalline silicon contact layer has a crystalline fraction between about 20 percent and about 80 percent, preferably between 50 percent and about 70 percent. In the embodiment wherein trimethylboron is used to provide boron dopants in the p-type microcrystalline silicon layer, the boron dopant concentration is maintained at between about 1×10¹⁸ atoms/cm² and about 1×10²⁰ atoms/cm².

In step 454, an intrinsic amorphous silicon layer 133A is deposited over the p-doped silicon layer 132. The intrinsic amorphous silicon layer 133A may be deposited to a thickness of 100 Å or less, more preferably 50 A or less. Certain embodiments of depositing an intrinsic amorphous silicon layer 133A comprises providing a gas mixture of hydrogen gas to silane gas in a ratio of about 20:1 or less. Silane gas may be provided at a flow rate between about 0.5 sccm/L and about 7 sccm/L. Hydrogen gas may be provided at a flow rate between about 4 sccm/L and 60 sccm/L. An RF power between 15 milliWatts/cm² and about 250 milliWatts/cm² may be provided to the showerhead. The pressure of the chamber may be maintained between about 0.1 Torr and 20 Torr, preferably between about 0.5 Torr and about 5 Torr. The deposition rate of the intrinsic amorphous silicon layer may be about 100 Å/min or more.

In step 456, an intrinsic microcrystalline silicon layer 133B is deposited over the intrinsic amorphous silicon layer 133A. The intrinsic microcrystalline silicon layer 133B may be deposited to a thickness of 1,000 Å or more, more preferably 10,000 Å or more. In certain embodiment, the intrinsic microcrystalline silicon layer 133B may be formed by depositing a first intrinsic microcrystalline silicon layer and a second intrinsic microcrystalline silicon layer. The first intrinsic microcrystalline silicon layer may be deposited by providing a hydrogen gas and silane gas at a ratio of over 200:1, preferably over 500:1. In one embodiment, the first intrinsic microcrystalline silicon layer may be deposited by providing a hydrogen gas and silane gas at a ratio between about 200:1 and about 1000:1. In one example, the silane flow rate is set to about 0.5 sccm/L and the hydrogen flow rate is set to about 230 sccm/L during this step. The second intrinsic microcrystalline silicon layer may be deposited by providing a hydrogen gas and silane gas at a ratio of under 200:1, preferably under 125:1. In one example, the silane flow rate is set to about 5 sccm/L and the hydrogen flow rate is set to about 63 sccm/L during this step.

Certain embodiments of depositing a first intrinsic microcrystalline silicon layer of layer 133B may comprise providing silane gas at a flow rate of 1 sccm/L or less. Hydrogen gas may pre provided at a flow rate of 50 sccm/L or more. An RF power between about 1,000 milliWatts/cm² or less may be provided to the showerhead. The pressure of the chamber is maintained between about 1 Torr and about 100 Torr, preferably between about 3 Torr and about 20 Torr, more preferably between about 4 Torr and about 12 Torr. The deposition rate of the first intrinsic microcrystalline silicon layer may be about 200 Å/min or less. In one aspect, the deposition regime of the first intrinsic microcrystalline layer is a slow deposition rate regime in order to promote conversion of the intrinsic amorphous silicon at least partially or substantially all to become high quality microcrystalline intrinsic silicon.

Certain embodiments of depositing a second intrinsic microcrystalline silicon layer of layer 133B may comprise providing silane gas at a flow rate between about 0.1 sccm/L and about 5 sccm/L. Hydrogen gas may be provided at a flow rate between about 5 sccm/L and about 400 sccm/L. In certain embodiments, the silane flow rate may be ramped up from a first flow rate to a second flow rate during deposition. In certain embodiments, the hydrogen flow rate may be ramped down from a first flow rate to a second flow rate during deposition. An RF power between about 100 milliWatts/cm² or greater may be provided to the showerhead. In certain embodiments, the power density may be ramped down from a first power density to a second power density during deposition. The pressure of the chamber is maintained between about 1 Torr and about 100 Torr, preferably between about 3 Torr and about 20 Torr, more preferably between about 4 Torr and about 12 Torr. The deposition rate of the second intrinsic microcrystalline silicon layer may be about 200 Å/min or more. The second intrinsic microcrystalline silicon layer has a crystalline fraction between about 20 percent and about 80 percent, preferably between 55 percent and about 75 percent.

In step 458, an n-doped silicon layer 136 is deposited over the substrate. Certain embodiments of a method depositing a n-doped silicon layer 136, may comprise depositing an optional first n-type amorphous silicon layer at a first silane flow rate and depositing a second n-type amorphous silicon layer over the first optional n-type amorphous silicon layer at a second silane flow rate lower than the first silane flow rate. The first optional n-type amorphous silicon layer may comprise providing a gas mixture of hydrogen gas to silane gas in a ratio of about 20:1 or less, such as about 5:5:1. Silane gas may be provided at a flow rate between about 1 sccm/L and about 10 sccm/L, such as about 5.5 sccm/L. Hydrogen gas may be provided at a flow rate between about 4 sccm/L and about 40 sccm/L, such as about 27 sccm/L. Phosphine may be provided at a flow rate between about 0.0005 sccm/L and about 0.0015 sccm/L, such as about 0.0095 sccm/L. In other words, if phosphine is provided in a 0.5% molar or volume concentration in a carrier gas, then the dopant/carrier gas mixture may be provided at a flow rate between about 0.1 sccm/L and about 3 sccm/L, such as about 1.9 sccm/L. An RF power between 25 milliWatts/cm² and about 250 milliWatts/cm², such as about 80 milliWatts/cm², may be provided to the showerhead. The pressure of the chamber may be maintained between about 0.1 Torr and about 20 Torr, preferably between about 0.5 Torr and about 4 Torr, such as about 1.5 Torr. The deposition rate of the first n-type amorphous silicon layer may be about 200 Å/min or more, such as about 561 Å/min. In the embodiment wherein phosphine is used to provide phosphorous dopants in the n-type amorphous silicon layer, the phosphorous dopants concentration is maintained at between about 1×10¹⁸ atoms/cm² and about 1×10²⁰ atoms/cm².

The second n-type amorphous silicon layer deposition may comprise providing a gas mixture of hydrogen gas to silane gas in a ratio of about 20:1 or less, such about 7.8:1. Silane gas may be provided at a flow rate between about 0.1 sccm/L and about 5 sccm/L, such as about 0.5 sccm/L and about 3 sccm/L, for example about 1.42 sccm/L. Hydrogen gas may be provided at a flow rate between about 1 sccm/L and about 10 sccm/L, such as about 6.42 sccm/L. Phosphine may be provided at a flow rate between 0.01 sccm/L and about 0.075 sccm/L, such as about 0.015 sccm/L and about 0.03 sccm/L, for example about 0.023 sccm/L. In other words, if phosphine is provided in a 0.5% molar or volume concentration in a carrier gas, then the dopant/carrier gas mixture may be provided at a flow rate between about 2 sccm/L and about 15 sccm/L, such as about 3 sccm/L and about 6 sccm/L, for example about 4.71 sccm/L. An RF power between 25 milliWatts/cm² and about 250 milliWatts/cm², such as about 60 milliWatts/cm², may be provided to the showerhead. The pressure of the chamber may be maintained between about 0.1 Torr and about 20 Torr, preferably between about 0.5 Torr and about 4 Torr, for example about 1.5 Torr. The deposition rate of the second n-type amorphous silicon layer may be about 100 Å/min or more, such as about 300 Å/min. The thickness of the second n-type amorphous silicon layer is less than o about 300 Å, such as about 20 Å and about 150 Å, for example about 80 Å. The second n-type amorphous silicon layer is heavily doped and has a resistivity of about 500 O-hm-cm or below. It is believed that the heavily (e.g., degenerately) n-type doped amorphous silicon provides improved ohmic contact with a TCO layer, such as layer TCO layer 140. Thus, cell efficiency is improved. The optional first n-type amorphous silicon is used to increase the deposition rate for the entire n-type amorphous silicon layer. It is understood that the n-type amorphous silicon layer may be formed without the optional first n-type amorphous silicon and may be formed primarily of the heavily (e.g., degenerately) doped second n-type amorphous layer.

Not wishing to be bound by theory unless explicitly set forth in the claims, in one theory, it is believed that the relatively thin intrinsic amorphous silicon layer 133A is at least partially converted to intrinsic microcrystalline silicon during processing. This partially converted intrinsic microcrystalline silicon acts as a seed layer improving the growth and deposition of the intrinsic microcrystalline silicon layer 133B therefore. It is also believed that it may be beneficial to deposit a first intrinsic microcrystalline silicon at a very high hydrogen gas to silane gas ratio of over 200:1, preferably over 500:1, since the very high ratio of hydrogen gas promotes the conversion of the intrinsic amorphous silicon layer 133A to become at least partially or substantially all intrinsic microcrystalline silicon. In one aspect, that the intrinsic amorphous silicon layer 133A may be deposited to a thickness of 100 Å or less, more preferably 50 Å or less, so that it takes so that it takes a reduced amount of time to convert the intrinsic amorphous silicon layer 133A to become at least partially or substantially all intrinsic microcrystalline silicon. In certain embodiments, the deposition of the first intrinsic microcrystalline layer may be performed for a duration of 300 seconds or less. It is also believed that the high hydrogen content in the plasma used to form the first intrinsic microcrystalline silicon layer is advantageous, since the high hydrogen content in the plasma will provide an increase in the amount bombardment of the surface of the intrinsic amorphous silicon layer and the growing intrinsic microcrystalline silicon layer during the deposition process. The higher bombardment can alter the surface morphology (e.g., roughness) of the underlying intrinsic amorphous silicon layer and/or the growing intrinsic microcrystalline silicon layer to provide an improved seed layer for the subsequently deposited second intrinsic microcrystalline silicon layer.

In another theory. It is believed that the intrinsic amorphous silicon layer 133A acts as a diffusion barrier layer reducing the migration of p-dopants (e.g., boron) in the p-doped silicon layer 132 into the intrinsic microcrystalline silicon layer 133B. It is also believed that the intrinsic amorphous silicon layer 133A will reduce the amount of diffusion of the p-type dopants within the deposited layers, due to ion bombardment of the p-doped layer during the subsequent intrinsic microcrystalline silicon layer deposition step(s). Thus, the p-i-n junction is more stable and the efficiency is improved.

The spacing during deposition between the top surface of a substrate disposed on the substrate receiving surface 432 and the showerhead 410 may be between 400 mil (10.2 mm) and about 1,200 mil (30.4 mm), preferably between 400 mil (10.2 mm) and about 800 mil (20.4 mm).

The flow rates in the present disclosure are expressed as sccm per interior chamber volume. The interior chamber volume is defined as the volume of the interior of the chamber in which a gas can occupy. For example, the interior chamber volume of chamber 400 is the volume defined by the backing plate 412 and by the walls 402 and bottom 404 of the chamber minus the volume occupied therein by the showerhead assembly (i.e., including the showerhead 410, suspension 414, center support 415) and by the substrate support assembly (i.e., substrate support 430, grounding straps 431). The RF powers in the present disclosure are expressed as Watts supplied to an electrode per substrate area. For example, for a RF power of 10,385 Watts supplied to a showerhead to process a substrate having dimensions of 220 cm×260 cm, the RF power would be 10,385 Watts/(220 cm×260 cm)=180 milliWatts/cm².

Referring to FIG. 4, in one embodiment, an optional plasma treatment process, or step 455, is performed on the surface of the deposited intrinsic amorphous silicon layer 133A prior to depositing the intrinsic microcrystalline silicon layer(s) 133B. In certain embodiments, the plasma treatment process comprise providing a hydrogen (H₂) gas at a flow rate between about 5 sccm/L and 100 sccm/L. In another embodiment, the plasma treatment process comprises providing helium (He), carbon dioxide (CO₂), argon (Ar), or other similar gas at a similar mass flow rate. An RF power between 10 milliWatts/cm² and about 250 milliWatts/cm² may be provided to the showerhead during the plasma treatment process. The pressure of the chamber during the plasma treatment process may be maintained between about 1 Torr and about 100 Torr, preferably between about 3 Torr and about 20 Torr, more preferably between 4 Torr and about 12 Torr. The spacing between the top surface of a substrate disposed on the substrate receiving surface 432 and the showerhead 410 may be between about 400 mil (10.2 mm) and about 1,200 mil (30.4 mm), preferably between 400 mil (10.2 mm) and about 800 mil (20.4 mm) during the plasma treatment process. Not wishing to be bound by theory unless explicitly set forth in the claims, it is believed that the plasma treatment process is useful, since the process provides an increased number of nucleation sites for the intrinsic microcrystalline layer to form on the treated intrinsic amorphous silicon layer, due to the change in the surface morphology (e.g., roughness) created by the plasma bombardment of the intrinsic amorphous silicon layer during processing. The improved in film morphology and increase the number nucleation sites can thus improve the intrinsic amorphous silicon layer's properties and reduce the time required to form the intrinsic microcrystalline layer of a desired thickness.

Examples of various processing steps that may be adapted to form one or more of the layers described herein to form a tandem solar cell may be found in the pending U.S. patent application Ser. No. 11/671,988 filed Feb. 6, 2007, entitled “Multi-Junction Solar Cells and Methods and Apparatuses for Forming the Same”, the pending U.S. patent application Ser. No. 12/178,289 filed Jul. 23, 2008, entitled “Multi-Junction Solar Cells and Methods and Apparatuses for Forming the Same,” and the pending U.S. patent application Ser. No. 11/426,127 filed Jun. 23, 2006, entitled “Methods and Apparatus for Depositing a Microcrystalline Silicon Film for Photovoltaic Device,” which are all incorporated by reference in their entirety to the extent not inconsistent with the present disclosure.

Referring back to FIGS. 3A-3B, in one embodiment of the system 500, one of the process chambers 531 is configured to deposit the p-type silicon layer(s) in the first p-i-n junction 120 or the second p-i-n junction 130 of a solar cell device, another one of the process chambers 531 is configured to deposit an intrinsic silicon layer of the first or the second p-i-n junction, and another of the process chambers 531 is configured to deposit the n-type silicon layer(s) of the first or the second p-i-n junction. As noted above, while a three chamber process configuration may have some contamination control advantages, it will generally have a lower substrate throughput than a two chamber processing system, and generally cannot maintain a desirable throughput when one or more of the processing chambers is brought down for maintenance.

In certain embodiments of the invention, the system 500 (e.g., FIG. 3A or FIG. 3B) is configured to form at least one of the p-i-n junctions, such as the first p-i-n junction 120 or the second p-i-n junction 130 illustrated in FIG. 1. In one embodiment, one of the process chambers 531 is configured to deposit the p-type silicon layer(s) of the second p-i-n junction 130 while the remaining process chambers 531 are each configured to deposit both the intrinsic type silicon layers, such as the intrinsic amorphous silicon layer 133A and the intrinsic microcrystalline silicon layer(s) 133B, and the n-doped silicon layer(s) of the second p-i-n junction 130. In one embodiment, the intrinsic type silicon layers and the n-type silicon layer(s) of the first p-i-n junction 120 or the second p-i-n junction 130 may be deposited in the same chamber without performing a seasoning process (e.g., intrinsic type layer deposited on the chamber walls) in between steps, which is used to minimize cross-contamination between the deposited layers, in between the deposition steps. While the discussion of the system 500 and its components references its use in forming the various elements of the second p-i-n junction 130 this configuration is not intended to be limiting as to the scope of the invention described herein, since the system 500 could be adapted to form the first p-i-n junction, the second p-i-n junction, both the first and second p-i-n junctions, or other combinations thereof without deviating from the basic scope of the invention described herein.

In one example, in which the substrate processing sequence performed in a system configured similarly to the system 500, a substrate enters the system 500 through the load lock chamber 510, the substrate is then transferred by the vacuum robot 522 into the process chamber 531 that is configured to deposit a p-type silicon layer(s) on the substrate, after depositing the p-type layer in process chamber 531 the substrate is then transferred by the vacuum robot 522 into another of the process chambers 531 that is configured to deposit both the intrinsic type silicon layers and the n-type silicon layer(s), and then after depositing the intrinsic-type layers and n-type layer(s) the substrate is returned to the load lock chamber 510 after which the substrate can be removed from the system. A continuous series of substrates can be loaded and maneuvered by the vacuum robot 522 from a process chamber that is adapted to deposit a p-type layer and then transfer each of the substrates to at least one subsequent processing chamber to form the i-n layers. In one embodiment, the first p-i-n junction 120 is formed in one system 500 and the second p-i-n junction 130 is formed in another system 500. In one case, a vacuum break, or exposure to ambient atmospheric conditions (e.g., air), will occur between the formation of the first p-i-n junction 120 and the second p-i-n junction 130 in different systems.

In a two chamber processing configuration, subsequent to deposition of the i-n layers in each of the chambers dedicated to producing the same, the process may be repeated. However, to preclude contamination being incorporated into the intrinsic layers formed on subsequent substrates, it has been found that performing a cleaning process, such as a seasoning process in each of the chambers dedicated to producing the i-n layers at some desired interval the device yield of the processing sequence can be improved. The seasoning process may generally comprises one or more steps that are used to remove prior deposited material from a processing chamber part and one or more steps that are used to deposit a material on the processing chamber part as discussed in accordance with one of the embodiments described herein. An example of a seasoning process and solar cell processing sequence that may be used is further described in the U.S. patent application Ser. No. 12/170,387 [Attorney docket # APPM 11710], filed Jul. 9, 2008, which is herein incorporated by reference.

While the foregoing is directed to embodiments of the present invention, other and further embodiments of the invention may be devised without departing from the basic scope thereof, and the scope thereof is determined by the claims that follow.

1. A method of forming a p-i-n junction over a substrate, comprising:
depositing a p-doped silicon layer over a surface of a substrate;
depositing an n-doped silicon layer over the surface of the substrate;
depositing an intrinsic amorphous silicon layer between the p-doped silicon layer and the n-doped silicon layer; and
depositing an intrinsic microcrystalline silicon layer on the intrinsic amorphous silicon layer.

2. The method of claim 1, wherein the intrinsic amorphous silicon layer is deposited to a thickness of 100 Å or less.

3. The method of claim 1, wherein the intrinsic amorphous silicon layer is deposited to a thickness of 50 Å or less.

4. The method of claim 1, wherein the p-i-n junction is formed over a first p-i-n junction, wherein the first p-i-n junction comprises an intrinsic amorphous silicon layer having a thickness of greater than about 1,000 Å.

5. The method of claim 1, wherein the p-doped layer is deposited on the surface of the substrate and the n-doped layer is deposited over the p-doped layer, wherein the substrate comprises a transparent substrate material and a transparent conductive oxide layer.

6. The method of claim 1, wherein the p-doped silicon layer comprises a p-doped microcrystalline silicon layer, and the n-doped silicon layer comprises an n-doped amorphous silicon layer.

7. The method of claim 1, further comprising exposing the intrinsic amorphous silicon layer to a plasma treatment process before depositing the intrinsic microcrystalline silicon layer, wherein the plasma treatment process comprises exposing the intrinsic amorphous silicon layer to a plasma comprising a gas selected from the group consisting of hydrogen, helium, argon and carbon dioxide.

8. A method of forming a p-i-n junction over a substrate, comprising:
depositing a p-doped silicon layer over a surface of a substrate;
depositing an n-doped silicon layer over the surface of the substrate;
depositing an intrinsic amorphous silicon layer between the p-doped silicon layer and the n-doped silicon layer;
depositing a first intrinsic microcrystalline silicon layer on the intrinsic amorphous silicon layer by providing hydrogen gas and silane gas at a ratio of greater than about 200:1; and
depositing a second intrinsic microcrystalline silicon layer on the first intrinsic microcrystalline silicon layer by providing hydrogen gas and silane gas at a ratio of less than about 200:1.

9. The method of claim 8, wherein depositing the first intrinsic microcrystalline silicon layer causes at least a portion of the intrinsic amorphous silicon layer to be converted to a layer comprising microcrystalline silicon.

10. The method of claim 9, wherein substantially all of the intrinsic silicon layer is converted to microcrystalline silicon.

11. The method of claim 8, wherein the p-doped layer is deposited on the surface of the substrate and the n-doped layer is deposited over the p-doped layer, wherein the substrate comprises a transparent substrate material and a transparent conductive oxide layer.

12. The method of claim 8, wherein the p-doped silicon layer comprises a p-doped microcrystalline silicon layer, and the n-doped silicon layer comprises an n-doped amorphous silicon layer.

13. The method of claim 8, further comprising exposing the intrinsic amorphous silicon layer to a plasma treatment process before depositing the first intrinsic microcrystalline silicon layer, wherein the plasma treatment process comprises exposing the intrinsic amorphous silicon layer to a plasma comprising a gas selected from the group consisting of hydrogen, helium, argon and carbon dioxide.

14. A method of forming a p-i-n junction over a substrate, comprising:
depositing a p-doped silicon layer over a surface of the substrate in a first process chamber disposed within a first processing system;
transferring the substrate from the first process chamber to a second process chamber which is disposed within the first processing system, wherein transferring the substrate is performed in a vacuum environment; and
depositing two or more layers over the surface of the p-doped silicon layer while the substrate is positioned in the second process chamber, comprising:
depositing an intrinsic amorphous silicon layer on the p-doped silicon layer;
depositing an intrinsic microcrystalline silicon layer on the intrinsic amorphous silicon layer; and
depositing an n-doped silicon layer on the intrinsic microcrystalline silicon layer.

15. The method of claim 14, wherein a first p-i-n junction is formed over a substrate that comprises a transparent substrate material and a transparent conductive oxide layer before depositing the p-doped silicon layer.

16. The method of claim 15, wherein the first p-i-n junction comprises an intrinsic amorphous silicon layer having a thickness of greater than about 1,000 Å.

17. The method of claim 14, wherein depositing an intrinsic microcrystalline silicon layer comprises:
depositing a first intrinsic microcrystalline silicon layer on the intrinsic amorphous silicon layer by providing hydrogen gas and silane gas at a ratio of greater than about 200:1; and
depositing a second intrinsic microcrystalline silicon layer on the first intrinsic microcrystalline silicon layer by providing hydrogen gas and silane gas at a ratio of less than about 200:1.

18. The method of claim 14, wherein the intrinsic amorphous silicon layer is deposited to a thickness of 100 Å or less.

19. The method of claim 14, wherein the intrinsic amorphous silicon layer is deposited to a thickness of 50 Å or less.

20. The method of claim 14, further comprising:
depositing a p-doped silicon layer on a surface of the substrate in a first process chamber disposed within a second processing system;
transferring the substrate from the first process chamber to a second process chamber disposed within the second processing system, wherein transferring the substrate is performed in a vacuum environment; and
depositing two or more layers over the surface of the p-doped silicon layer while the substrate is positioned in the second process chamber, comprising:
depositing an intrinsic amorphous silicon layer on the p-doped silicon layer; and
depositing an n-doped amorphous silicon layer on the intrinsic amorphous silicon layer before depositing the p-doped silicon layer over the surface of the substrate in the first process chamber disposed within the first processing system.

21. The method of claim 20, further comprising transferring the substrate from the second process chamber disposed within the second processing system to the first process chamber disposed within the first processing system after depositing an n-doped amorphous silicon layer on the intrinsic amorphous silicon layer, wherein transferring the substrate from the second process chamber to the first process chamber includes exposing the substrate to air.

22. The method of claim 14, wherein the p-doped silicon layer comprises a p-doped microcrystalline silicon layer, and the n-doped silicon layer comprises an n-doped amorphous silicon layer.
